(19) United States
(12) Patent Application Publication
(10) Pub. No.: US 2009/0298234 A1
(43) Pub. Date: Dec. 3, 2009

(54) METHOD OF FABRICATING SEMICONDUCTOR CHIP PACKAGE, SEMICONDUCTOR WAFER, AND METHOD OF SAWING THE SEMICONDUCTOR WAFER

(76) Inventors: Teak-hoon Lee, Hwaseong-si (KR); Pyoung-wan Kim, Suwon-si (KR); Nam-seog Kim, Yongin-si (KR)

Correspondence Address: F. CHAU & ASSOCIATES, LLC, 130 WOODBURY ROAD, WOODBURY, NY, 11797, US

(21) Appl. No.: 12/359,820

(22) Filed: Jan. 26, 2009

(30) Foreign Application Priority Data
May 27, 2008 (KR) 10-2008-0049271

(51) Int. Cl. H01L 21/78

(52) U.S. Cl. 438/114; 257/E21.599; 438/124

(57) ABSTRACT

A method of fabricating a semiconductor chip package, in which a protection layer is formed on a scribe lane of a wafer including a plurality of semiconductor chips, an encapsulation layer is formed on the semiconductor chips and the protection layer, and at least two types of lasers having different respective wavelengths are sequentially irradiated to the scribe lane so as to separate the semiconductor chips. Therefore, the wafer can be protected from the laser that is used to saw the encapsulation layer.

### CROSS-REFERENCE TO RELATED PATENT APPLICATION

This application claims the benefit of Korean Patent Application No. 10-2008-0049271, filed on May 27, 2008, in the Korean Intellectual Property Office, the disclosure of which is incorporated herein in its entirety by reference.

### BACKGROUND

This disclosure relates to a method of fabricating a semiconductor chip package and, more particularly, to a method of fabricating a wafer-level semiconductor chip package, a semiconductor wafer, and a method of sawing the semiconductor wafer.

In general, a method of fabricating semiconductor devices includes a process of fabricating semiconductor chips that include integrated circuits formed on a silicon substrate, an electrically die sorting (EDS) process in which the semiconductor chips are electrically examined to identify defective semiconductor chips, and a packaging process for protecting the semiconductor chips. Recently, semiconductor devices have been developed to have better performance and higher integration level. Therefore, the importance of packaging techniques has increased considerably.

Semiconductor packages provide electrical connections for semiconductor chips to the outside and protect the semiconductor chips. As electronic devices are manufactured to be small, lightweight, and multi-functional, demands for small, lightweight, economical, and reliable semiconductor chips have increased. Accordingly, a wafer-level packaging method has been developed. In the wafer-level packaging method, a series of assembly processes including die-bonding, molding, marking, and the like are performed when semiconductor chips printed on a wafer are attached to each other, and then a sawing process is performed on the resultant structure to fabricate the final products.

Because a series of processes including an assembly process are performed on all the semiconductor chips in the wafer, at the same time, wafer-level packaging contributes to a substantial decrease in the manufacturing costs of a semiconductor device. In addition, a packaging function and functions of semiconductor chips can be almost completely integrated, and thermal and electrical characteristics of a semiconductor device can be improved. Furthermore, wafer-level packaging enables packages to be manufactured in a small size comparable to that of semiconductor chips.

### SUMMARY

According to an exemplary embodiments of the present invention, there is provided a method of fabricating a semiconductor chip package, the method including: forming a protection layer on a scribe lane of a wafer comprising a plurality of semiconductor chips; forming an encapsulation layer on the plurality of semiconductor chips and the protection layer; and separating the plurality of semiconductor chips by sequentially irradiating at least two types of lasers adjacent to the scribe lane.

The separating of the plurality of semiconductor chips includes: irradiating a first laser to the scribe lane so as to saw a portion of the encapsulation layer corresponding to the protection layer; and irradiating a second laser having a shorter wavelength than the first laser to the scribe lane so as to saw the protection layer and the wafer.

The protection layer hardly absorbs the first laser but absorbs well the second laser. The protection layer includes at least one material selected from the group consisting of Cu, Ti, Ni, Ag, Au, an alloy thereof, and a mixture thereof.

The first laser may be at least one laser selected from the group consisting of an infrared-ray laser, a CO₂ laser, and a green laser. The second laser may be an ultraviolet-ray laser.

The method may further include forming a plurality of connection members respectively, electrically connected to the plurality of semiconductor chips in the wafer, wherein the encapsulation layer exposes a top portion of each connection member.

The method may further include: forming a metal pad of each semiconductor chip on the wafer; forming a first interlayer-insulating layer exposing a portion of the metal pad on the wafer; forming a metal interconnection layer on the first interlayer-insulating layer; and forming a second interlayer-insulating layer exposing a portion of the metal interconnection layer on the metal interconnection layer, wherein each connection member is electrically connected to the corresponding metal interconnection layer.

The plurality of connection members may include at least one material selected from the group consisting of a solder ball, a solder bump, a gold bump, and a nickel bump. The encapsulation layer may include an epoxy molding compound (EMC).

According to an exemplary embodiment of the present invention, there is provided a method of sawing a semiconductor wafer including: a wafer having a plurality of semiconductor chips; and an encapsulation layer formed on the wafer, the method comprising: forming a protection layer on a scribe lane of the wafer; irradiating a first laser to the scribe lane on which the protection layer is formed so as to saw a portion of the encapsulation layer corresponding to the protection layer; and irradiating a second laser having a shorter wavelength than the first laser to the scribe lane so as to saw the protection layer and the wafer.

The protection layer hardly absorbs the first laser but absorbs well the second laser. The protection layer may include at least one material selected from the group consisting of Cu, Ti, Ni, Ag, Au, an alloy thereof, or a mixture thereof.

The first laser may include at least one laser selected from the group consisting of an infrared-ray laser, a CO₂ laser, and a green laser. The second laser may be an ultraviolet-ray laser.

According to an exemplary embodiment of the present invention, there is provided a semiconductor wafer including: a plurality of semiconductor chips formed in a wafer; a protection layer formed on a scribe lane of the wafer; and an encapsulation layer formed on the plurality of semiconductor chips and the protection layer, wherein the protection layer hardly absorbs a first laser but does absorb well a second laser having a shorter wavelength than the first laser, wherein the first laser is used to saw the encapsulation layer and the second laser is used to saw the wafer and the protection layer.

The semiconductor wafer may further include a plurality of connection members formed on the wafer, and electrically connected to the plurality of semiconductor chips, respectively, wherein the encapsulation layer exposes a top portion of each connection member.

The semiconductor wafer may further include: a metal pad of each semiconductor chip on the wafer; a first interlayer-insulating layer exposing a portion of the metal pad on the wafer; a metal interconnection layer on the first interlayer-insulating layer; and a second interlayer-insulating layer exposing a portion of the metal interconnection layer on the metal interconnection layer, wherein each connection member is electrically connected to the corresponding metal interconnection layer.

The first laser may include at least one laser selected from the group consisting of an infrared-ray laser, a CO₂ laser, and a green laser. The second laser may be an ultraviolet-ray laser. The plurality of connection members may include at least one material selected from the group consisting of a solder ball, a solder bump, a gold bump, and a nickel bump.

### BRIEF DESCRIPTION OF THE DRAWINGS

The above and other features and advantages of exemplary embodiments of the present invention will be understood in more detail from the following descriptions taken in conjunction with the attached drawings, in which:

FIG. 1 shows an image of a wafer including a plurality of semiconductor chips;

FIG. 2 is an enlarged view of a portion of the wafer of FIG. 1;

FIG. 3 is a sectional view of a semiconductor wafer according to an exemplary embodiment of the present invention;

FIGS. 4-11 are sectional views for illustrating a method of fabricating a semiconductor chip package according to an exemplary embodiment of the present invention;

FIG. 12 is a graph of an absorption degree with respect to a wavelength of different respective materials that are used for forming a protective layer that is formed above a scribe lane of a semiconductor wafer according to an exemplary embodiment of the present invention;

FIG. 13 is a flow chart illustrating a method of fabricating a semiconductor chip package, according to an exemplary embodiment of the present invention; and

FIG. 14 is a flow chart illustrating a method of sawing a semiconductor wafer, according to an exemplary embodiment of the present invention.

### DETAILED DESCRIPTION OF EXEMPLARY EMBODIMENTS

Reference will now be made in detail to exemplary embodiments, examples of which are illustrated in the accompanying drawings. The exemplary embodiments are not limited to the embodiments illustrated hereinafter, however, and the exemplary embodiments herein are rather introduced to provide easy and complete understanding of the scope and spirit of the exemplary embodiments.

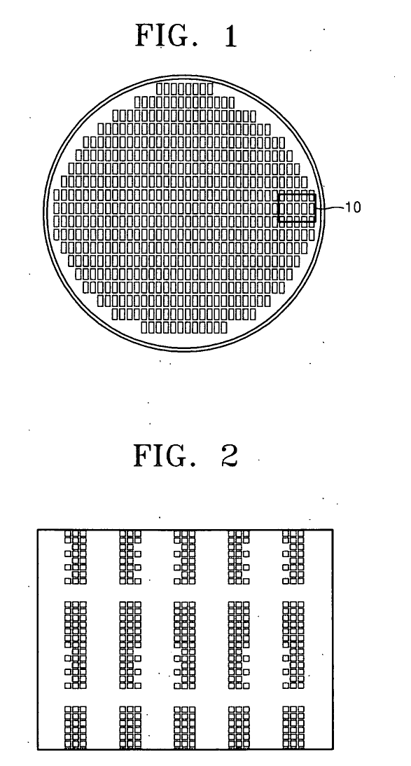

FIG. 1 shows an image of a wafer including a plurality of semiconductor chips, and FIG. 2 is an enlarged view of a portion 10 of the wafer shown in FIG. 1.

Referring to FIGS. 1 and 2, in general, a few to thousands of semiconductor chips are formed in a wafer by an integrated-circuit fabrication process. Semiconductor chips formed in the wafer are separated from each other by sawing along a scribe lane. The separating process is referred to as a sawing process. The sawing process can also be called a singulation process, because the semiconductor chips integrated in the wafer are separated into individual pieces. The sawing process can be a blade sawing process or a laser sawing process.

When a wafer and an encapsulation layer formed on the wafer are sawed by blade sawing, different blades are used for the different operations. More specifically, the blade used for sawing the encapsulation layer has a greater thickness than the width of the scribe lane of the wafer. Therefore, a first blade having a relatively greater thickness is used to saw only the encapsulation layer and then a second blade having a relatively smaller thickness is used to saw the wafer. Accordingly, when the first blade is used, the wafer can be chipped off or cracked.

When a wafer and an encapsulation layer formed on the wafer are sawed by laser sawing, lasers of various wavelengths can be used. When an ultraviolet (UV) laser is used, the sawing rate is low. When an infrared (IR) laser is used, the wafer hardly absorbs the IR laser, because the wafer is generally formed of silicon. Therefore, the IR laser is not appropriate for sawing. When a green (Yb:YAG) laser with a long wavelength or a CO₂ laser with a long wavelength is used, the wafer may be damaged.

Accordingly, according to an exemplary embodiment of the present invention, the sawing process is performed in such a way that lasers of different wavelengths are sequentially irradiated to the scribe lane of the wafer and the encapsulation layer. Specifically, a first laser having a relatively long wavelength and a second laser having a relatively short wavelength are sequentially irradiated to increase the sawing rate. This exemplary embodiment will now be described in detail.

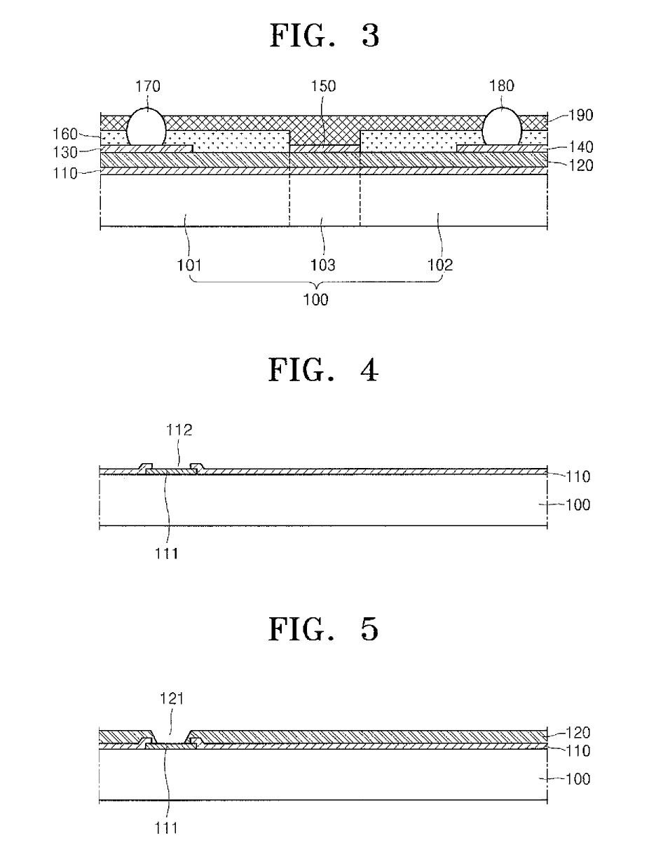

FIG. 3 illustrates a portion of a semiconductor wafer according to an exemplary embodiment of the present invention, neighboring semiconductor chips and a scribe lane interposed between the semiconductor chips.

Referring to FIG. 3, the semiconductor wafer includes a wafer 100, a passivation layer 110, a first interlayer-insulating layer 120, first and second metal interconnection layers 130 and 140, a protection layer 150, first and second connection members 170 and 180, a second interlayer-insulating layer 160, and an encapsulation layer 190.

The wafer 100 may be a silicon wafer, and semiconductor chips including various semiconductor devices, formed using a semiconductor fabrication process, may be formed in the wafer 100. First and second semiconductor chips 101 and 102 defined by a scribe lane 103 are arranged in the wafer 100. Although FIG. 3 illustrates only two semiconductor chips, it would be seen by one of ordinary skill in the art that the wafer 100 can also include three or more semiconductor chips.

The passivation layer 110 is formed on the wafer 100, and protects a pattern inside the wafer 100 and a metal pad (not shown) formed on the wafer 100. The passivation layer 110 may be formed of an oxide such as SiO₂, a nitride such as Si₃N₄, phosphor silicate glass (PSG), or a mixture thereof.

The first interlayer-insulating layer 120 formed on the passivation layer 110 has a uniform thickness, and exposes a portion of the metal pad (not shown). The first interlayer-insulating layer 120 may be a polymer-based insulating material.

The first metal interconnection layer 130 is formed on the first interlayer-insulating layer 120 and is connected to a metal pad (not shown) of the first semiconductor chip 101. The second metal interconnection layer 140 is formed on the first interlayer-insulating layer 120 and is connected to a metal pad (not shown) of the second semiconductor chip 102. The first and second metal interconnection layers 130 and 140 are regions in which interconnection terminals are to be formed. The first and second metal interconnection layers 130 and 140 are used to electrically extend a metal pad.

Each of the first and second metal interconnection layers 130 and 140 may be a metal layer. In some cases, each of the first and second metal interconnection layers 130 and 140 may include a nickel (Ni) layer, a copper (Cu) layer, and a titanium (Ti) layer. More specifically, to form the first and second metal interconnection layers 130 and 140, seed metal is deposited on portions of the first interlayer-insulating layer 120 corresponding to the first and second semiconductor chips 101 and 102, and then a photolithography process is performed.

The protection layer 150 is formed on a portion of the first interlayer-insulating layer 120 corresponding to the scribe lane 103. In the current exemplary embodiment, the protection layer 150 may include at least one material selected from the group consisting of Cu, Ti, silver (Ag), gold (Au), and alloys thereof. In an exemplary embodiment of the present invention, the protection layer 150 may be formed when the first and second metal interconnection layers 130 and 140 are formed. More specifically, to form the protection layer 150, a seed metal is deposited on the portion of the first interlayer-insulating layer 120 corresponding to the scribe lane 103 when seed metals are deposited on the portions of the first interlayer-insulating layer 120 corresponding to the first and second semiconductor chips 101 and 102, and then a photolithography process is performed.

In a sawing process for a semiconductor wafer, the protection layer 150 barely absorbs a first laser of a long wavelength, which is used to saw the encapsulation layer 190, and thus, when exposed to the first laser, the protection layer 150 is not sawed. The first laser may be a CO₂ laser, an IR laser or a green laser. On the other hand, the protection layer 150 absorbs a second laser, which has a shorter wavelength than the first laser, and thus, when exposed to the second laser, the protection layer 150 is sawed. The second laser may be a UV laser. Accordingly, the protection layer 150 protects the wafer 100 from the first laser and, thus, chipping-off or cracking of the wafer 100 can be prevented.

The second interlayer-insulating layer 160 may be formed on the first interlayer-insulating layer 120, the first and second metal interconnection layers 130 and 140, and the first and second semiconductor chips 101 and 102, and exposes portions of the first and second metal interconnection layers 130 and 140 and the protection layer 150. The thickness of the second interlayer-insulating layer 160 is uniform. In the current exemplary embodiment, the second interlayer-insulating layer 160 may be a polymer-based insulating material.

The first connection member 170 is formed on the first metal interconnection layer 130 and is electrically connected to the first metal interconnection layer 130. The second connection member 180 is formed on the second metal interconnection layer 140 and is electrically connected to the second metal interconnection layer 140. Accordingly, the first and second connection members 170 and 180 are electrically connected to the first and second semiconductor chips 101 and 102 through the first and second metal interconnection layers 130 and 140, respectively.

In the current exemplary embodiment, each of the first and second connection members 170 and 180 may be a solder ball, a solder bump, an Au bump, a Ni bump or a Cu bump. In the current exemplary embodiment, the first and second connection members 170 and 180 may be disposed on the first and second metal interconnection layers 130 and 140 and then a heat reflow process can be performed thereon, so that the first and second connection members 170 and 180 have a junction with the first and second metal interconnection layers 130 and 140, respectively.

The encapsulation layer 190 is formed on the second interlayer-insulating layer 160 formed on the first and second semiconductor chips 101 and 102, and the protection layer 150 formed on the scribe lane 103, and protects the semiconductor wafer. In addition, the encapsulation layer 190 exposes top portions of the first and second connection members 170 and 180 so that the first and second connection members 170 and 180 can be electrically connected to an external terminal (not shown).

In the current exemplary embodiment, the encapsulation layer 190 may be formed of an epoxy molding compound (EMC). The encapsulation layer 190, however, can also be formed of other materials using various methods. When the encapsulation layer 190 is formed of EMC, the encapsulation layer 190 is not damaged and edge cracks are not formed even when strong impacts are inflicted in the sawing process, because EMC is stronger than an epoxy resin.

In an exemplary embodiment of the present invention, the encapsulation layer 190 may be formed on, in addition to a top portion of the wafer 100, a side or bottom portion of the wafer 100. The encapsulation layer 190 may prevent chipping-off or cracking of the wafer 100 when impacts are inflicted in package assembly and mounting processes. The encapsulation layer 190 also protects patterns from stress generated when a re-distribution metal layer and a connection bump are formed in the subsequent process.

FIGS. 4-11 are sectional views for illustrating a method of fabricating a semiconductor chip package according to an exemplary embodiment of the present invention. Although FIG. 3 illustrates the first and second semiconductor chips 101 and 102 and the scribe lane 103 interposed between the first and second semiconductor chips 101 and 102, FIGS. 4-11 illustrates only the first semiconductor chip 101 and the scribe lane 103 in order to provide an easy understanding of the scope and spirit of the current exemplary embodiment.

Referring to FIG. 4, a metal pad 111 is formed on a wafer 100 including the first semiconductor chip 101. The metal pad 111 electrically connects the first semiconductor chip 101 to the outside. The metal pad 111 may be formed of aluminum or Cu.

Then, a passivation layer 110 having a first opening 112 that exposes a portion of the metal pad 111 is formed on the wafer 100. The passivation layer 110 protects a pattern of the wafer 100 and the metal pad 111, and may include an oxide, such as SiO₂, a nitride, such as Si₃N₄, PSG, or a mixture thereof. More specifically, to form the passivation layer 110, SiO₂, Si₃N₄, or PSG is deposited by chemical vapor deposition (CVD) and then a photolithography process is performed thereon.

Referring to FIG. 5, a first interlayer-insulating layer 120 having a second opening 121 that exposes the portion of the metal pad 111 that is exposed by the first opening 112 is formed on the passivation layer 110. More specifically, to form the first interlayer-insulating layer 120, a polymer-based insulating material is deposited on the passivation layer 110 and then a photolithography process is performed thereon.

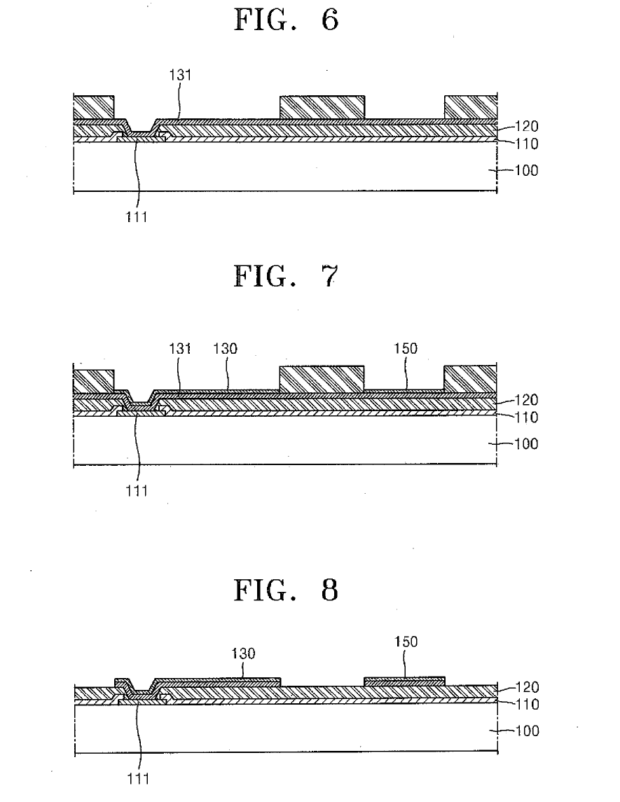

Referring to FIG. 6, a seed metal 131 is deposited on the first interlayer-insulating layer 120 by sputtering, and then a photolithography process is performed thereon. In the current exemplary embodiment, the seed metal 131 may be Cu, Ti, Ti nitride, Ti/W, Pt/Si, Al, or an alloy thereof.

Referring to FIG. 7, a first metal interconnection layer 130 and a protection layer 150 are formed on the seed metal 131 by electroplating. The thickness of each of the metal interconnection layer 130 and the protection layer 150 may be uniform. In the current exemplary embodiment, each of the first metal interconnection layer 130 and the protection layer 150 may be formed of Cu, Ti, Ni, Ag, gold, an alloy thereof, or a mixture thereof. Referring to FIG. 8, a photoresist is removed and the seed metal 131 is etched, thereby exposing the first metal interconnection layer 130 and the protection layer 150.

Referring to FIG. 9, a second interlayer-insulating layer 160 having a third opening 161 and a fourth opening 162 are formed on the first interlayer-insulating layer 120. The third opening 161 exposes a portion of the first metal interconnection layer 130, and the fourth opening 162 exposes the protection layer 150. More specifically, to form the second interlayer-insulating layer 160, a polymer-based insulating material is deposited and then a photolithography process is performed thereon.

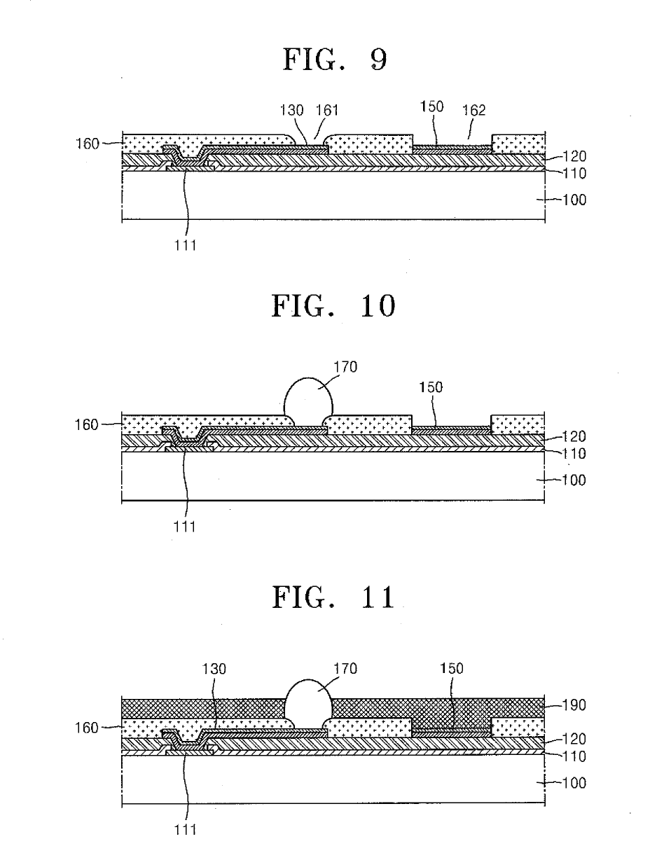

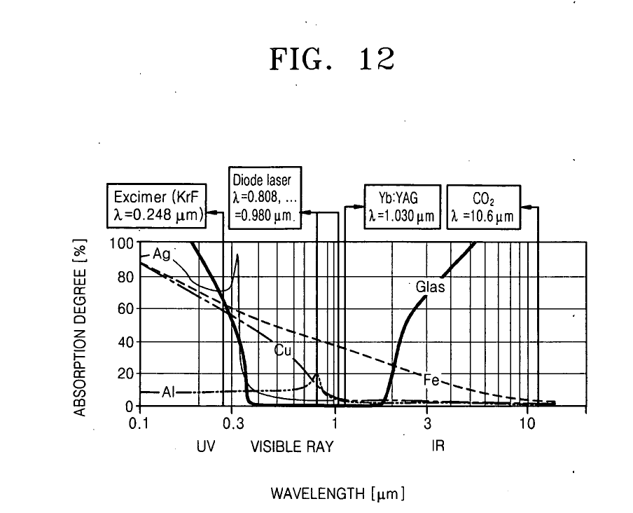

Referring to FIG. 10, a first connection member 170 is formed on the portion of the first metal interconnection layer 130 exposed by the third opening 161. More specifically, the first connection member 170 is disposed on the first metal interconnection layer 130 and then subjected to a heat reflow process so that the first connection member 170 forms a junction with the first metal interconnection layer 130. The first connection member 170 is electrically connected to the metal pad 111 through the first metal interconnection layer 130 and to the first semiconductor chip 101. In the current exemplary embodiment, the connection member 170 may be a solder ball, a solder bump, a gold bump, a Cu bump or a Ni bump.

Referring to FIG. 11, an encapsulation layer 190 is formed on the second interlayer-insulating layer 160 and the protection layer 150. In this case, the encapsulation layer 190 exposes a top portion of the first connection member 170 so that the first connection member 170 can be connected to an external terminal (not shown). The encapsulation layer 190 may be formed of, for example, an epoxy molding compound. As described above, however, the encapsulation layer 190 can also be formed of other materials using various methods. In the current exemplary embodiment, the encapsulation layer 190 covers a surface of the wafer 100. The structure of encapsulation layer 190, however, is not limited thereto. In this regard, an encapsulation layer can also cover other surfaces of a wafer to prevent permeation of impurities into a pattern of the wafer.

In an exemplary embodiment of the present invention, the thickness of the semiconductor chip 101 (see FIG. 3) may be 500 μm or smaller, and the thickness of the encapsulation layer 190 may be in a range of 50 to 300 μm.

FIG. 12 is a graph showing an absorption degree with respect to a wavelength of different respective materials used for forming a protective layer on a scribe lane of a semiconductor wafer according to an exemplary embodiment of the present invention.

Referring to FIG. 12, an x-axis represents a wavelength (unit:μm) and a y-axis represents an absorption degree (unit: %). Examples of a laser having a longer wavelength than a visible-ray laser include an IR laser, a CO₂ laser and a green (Yb:YAG) laser. The IR laser has a wavelength of 3 μm or more, the CO₂ laser has a wavelength of 10.6 μm, and the green laser has a wavelength of 1.030 μm. On the other hand, examples of a laser having a shorter wavelength than the visible-ray laser include an UV laser and an excimer laser. The UV laser has a wavelength of 0.3 μm or less, and the excimer laser has a wavelength of 0.248 μm.

In general, when exposed to a laser having a short wavelength, a wafer including semiconductor chips is efficiently, quickly sawed, but an encapsulation layer formed on the wafer is slowly sawed.

Accordingly, according to an exemplary embodiment of the present invention, a protection layer that barely absorbs a first laser having a relatively long wavelength, such as the IR laser, the CO₂ laser or the green (Yb:YAG) laser, but absorbs a second laser having a relatively short wavelength, such as the UV laser, is formed between a wafer and an encapsulation layer, and the encapsulation layer is sawed with the first laser and the wafer is sawed with the second laser.

In this exemplary embodiment, the protection layer is barely sawed when exposed to the first laser because the protection layer hardly absorbs the first laser, but the protection layer is sawed together with the wafer because the protection layer absorbs well the second laser. As described above, the protection layer protects the wafer from the first laser and damage to the wafer can be prevented. In addition, the encapsulation layer can be quickly sawed with the first laser and the wafer can be quickly sawed with the second laser and, thus, overall, the wafer including the plurality of semiconductor chips can be quickly sawed. Accordingly, the yield of semiconductor chip packages is increased.

As described above, a protection layer formed on a scribe lane in a wafer may be formed of Cu, Ag, an alloy thereof, or a mixture thereof. Referring to FIG. 12, Cu or Ag hardly absorbs light having a long wavelength of 1 μm or more, but absorbs light having a short wavelength very well. Therefore, Cu and Ag are suitable to be used between the wafer and the encapsulation layer.

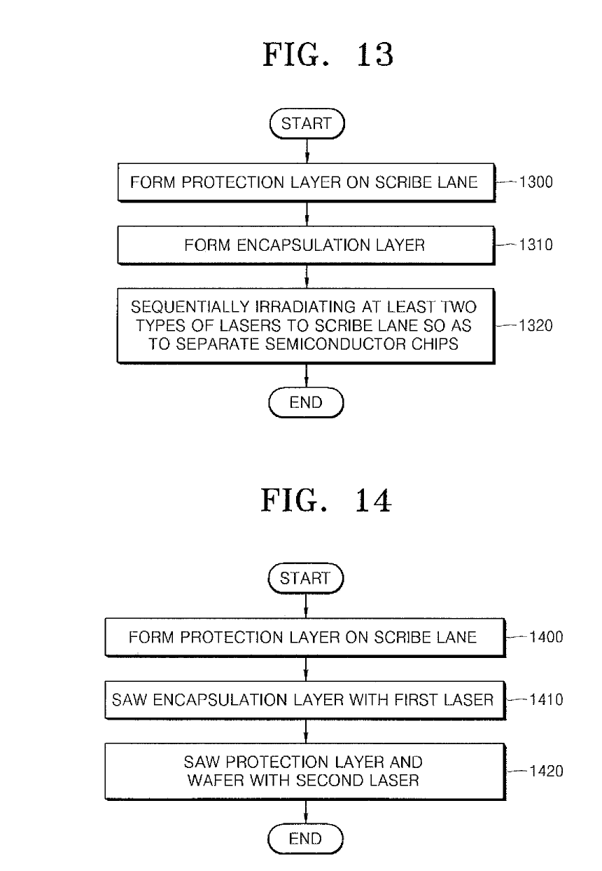

FIG. 13 is a flow chart illustrating a method of fabricating a semiconductor chip package, according to an exemplary embodiment of the present invention.

Referring to FIG. 13, in Operation 1300, a protection layer is formed on a scribe lane of a wafer including a plurality of semiconductor chips.

In Operation 1310, an encapsulation layer is formed on the protection layer covering the semiconductor chips.

In Operation 1320, at least two types of lasers are sequentially irradiated to the scribe lane to separate the semiconductor chips. In an exemplary embodiment of the present invention, a first laser is irradiated to the scribe lane to saw the encapsulation layer formed on the protection layer, and then a second laser having a shorter wavelength than the first laser is irradiated to the scribe lane to saw the protection layer and the wafer.

According to an exemplary embodiment of the present invention, the method of fabricating a semiconductor chip package may further include forming a plurality of connection members respectively electrically connected to the semiconductor chips on the wafer, in which the encapsulation layer exposes a top portion of each connection member.

According to an exemplary embodiment of the present invention, the method of fabricating a semiconductor chip package may further include: forming a metal pad on the semiconductor chips in the wafer; forming a first interlayer-insulating layer exposing a portion of the metal pad on the wafer; forming a metal interconnection layer on the first interlayer-insulating layer; and forming a second interlayer-insulating layer exposing a portion of the metal interconnection layer on the metal interconnection layer, in which the connection members may be electrically connected to the metal interconnection layer.

FIG. 14 is a flow chart illustrating a method of sawing a semiconductor wafer, according to an exemplary embodiment of the present invention.

Referring to FIG. 14, the method of sawing a semiconductor wafer that includes: a wafer including a plurality of semiconductor chips; and an encapsulation layer formed on the wafer, the method including the following operations.

In Operation 1400, a protection layer is formed on a scribe lane of the wafer.

In Operation 1410, a first laser is irradiated to the scribe lane so as to saw the encapsulation layer formed on the protection layer.

In Operation 1420, a second laser having a shorter wavelength than the first laser is irradiated to the scribe lane so as to saw the protection layer and the wafer.

An exemplary embodiment of the present invention can also be embodied as computer readable codes formed on a computer readable recording medium. The computer readable recording medium is any data storage device that can store data that can thereafter be read by a computer system. Examples of the computer readable recording medium include read-only memory (ROM), random-access memory (RAM), CD-ROMs, magnetic tapes, floppy disks, optical data storage devices, and carrier waves (such as data transmission through the Internet). The computer readable recording medium can also be distributed over network coupled computer systems so that the computer readable code is stored and executed in a distributed fashion. In an exemplary embodiment, a program stored in a recording medium is expressed in a series of instructions used directly or indirectly within a device with a data processing capability, such as, a computer. Thus, the term “computer” involves all devices with data processing capability in which a particular function is performed according to a program using a memory, input/output devices, and arithmetic logics. For example, a panel driving apparatus can be considered a computer for performing a panel driving operation.

While the present invention has been particularly shown and described with reference to exemplary embodiments thereof, it will be understood by those of ordinary skill in the art that various changes in form and details may be made therein without departing from the spirit and scope of the present invention, as defined by the following claims.

1. A method of fabricating a semiconductor chip package, the method comprising:
forming a protection layer on a scribe lane of a wafer having a plurality of semiconductor chips;
forming an encapsulation layer on the plurality of semiconductor chips and the protection layer; and
separating the plurality of semiconductor chips by sequentially irradiating at least two different types of lasers adjacent to the scribe lane.

2. The method of claim 1, wherein the separating of the plurality of semiconductor chips comprises:
irradiating a first laser having a known wavelength to the scribe lane so as to saw a portion of the encapsulation layer corresponding to the protection layer; and
irradiating a second laser having a shorter wavelength than the wavelength of the first laser to the scribe lane so as to saw the protection layer and the wafer.

3. The method of claim 2, wherein the protection layer hardly absorbs the first laser but absorbs the second laser well.

4. The method of claim 3, wherein the protection layer comprises at least one material selected from the group consisting of Cu, Ti, Ni, Ag, Au, an alloy thereof, and a mixture thereof.

5. The method of claim 2, wherein the first laser is at least one laser selected from the group consisting of an infrared-ray laser, a CO₂ laser, and a green laser.

6. The method of claim 2, wherein the second laser is an ultraviolet-ray laser.

7. The method of claim 1, further comprising forming a plurality of connection members respectively, electrically connected to the plurality of semiconductor chips in the wafer, wherein
the encapsulation layer exposes a top portion of each connection member.

8. The method of claim 7, further comprising:
forming a metal pad on each semiconductor chip on the wafer;
forming a first interlayer-insulating layer exposing a portion of the metal pad on the wafer;
forming a metal interconnection layer on the first interlayer-insulating layer; and
forming a second interlayer-insulating layer exposing a portion of the metal interconnection layer on the first interlayer-insulating layer, wherein
each connection member is electrically connected to the corresponding metal interconnection layer.

9. The method of claim 7, wherein the plurality of connection members comprises at least one material selected from the group consisting of a solder ball, a solder bump, a gold bump, a copper bump and a nickel bump.

10. The method of claim 1, wherein the encapsulation layer comprises an epoxy molding compound (EMC).

11. A method of sawing a semiconductor wafer including a plurality of semiconductor chips and an encapsulation layer formed on the wafer, the method comprising:
forming a protection layer on a scribe lane of the wafer;
irradiating a first laser having a predetermined wavelength to the scribe lane on which the protection layer is formed so as to saw a portion of the encapsulation layer corresponding to the protection layer; and
irradiating a second laser having a shorter wavelength than the wavelength of the first laser to the scribe lane so as to saw the protection layer and the wafer.

12. The method of claim 11, wherein the protection layer hardly absorbs the first laser but absorbs the second laser well.

13. The method of claim 12, wherein the protection layer comprises at least one material selected from the group consisting of Cu, Ti, Ni, Ag, Au, an alloy thereof, or a mixture thereof.

14. The method of claim 11, wherein the first laser is at least one laser selected from the group consisting of an infrared-ray laser, a CO₂ laser, and a green laser.

15. The method of claim 11, wherein the second laser is an ultraviolet-ray laser.

16-20. (canceled)
